(19) United States
(12) Patent Application Publication
(10) Pub. No.: US 2016/0109491 A1
(43) Pub. Date: Apr. 21, 2016

(54) GRID TOPOLOGY MAPPING WITH VOLTAGE DATA

(71) Applicant: Itron, Inc., Liberty Lake, WA (US)

(72) Inventor: James Lee Kann, Mica, WA (US)

(21) Appl. No.: 14/518,564

(22) Filed: Oct. 20, 2014

(51) Int. Cl. G01R 19/25; G01R 13/02; G01R 19/165; G01R 31/04

(52) U.S. Cl. CPC G01R 19/2506; G01R 31/04; G01R 13/02; G01R 19/16528

(57) ABSTRACT

A power line configuration or topology may be determined by identifying metering nodes that have time-stamped voltage values that correlate with voltage values measured at a transformer or other metering nodes at substantially the same time. A correlation between the time-stamped voltage values may be calculated by, in some examples, comparing a difference of a first time-stamped voltage value of a meter and a second time-stamped voltage value of a transformer or the second metering node to a predetermined threshold. If the difference is below the threshold, the metering node may be determined to be connected to the transformer or second metering node by a power distribution line.

### BACKGROUND

Smart meters and other devices in the smart grid provide increasingly sophisticated analysis of data to better manage electrical distribution. Aggregating data from smart meters allows utility companies to anticipate bottlenecks, avoid power failures, and generally optimize grid operation. Transformers step down medium transmission voltage to household voltage levels for supply to connected meters. Performing the sophisticated analysis and leveraging the information from the smart meters and other network nodes requires an accurate knowledge of which meters are connected to which transformers.

Current utility and distribution companies may or may not maintain physical connectivity information for individual meters. Where such information is collected, it is frequently poorly maintained and error prone. Line workers may change connections under time pressure to alleviate local power problems without updating appropriate records. Because transformers usually stay in service for decades, errors within the connectivity information can accumulate and degrade smart grid functionality. Most methods of remedying these errors include manually inspecting the devices in the field.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items. Moreover, the figures are intended to illustrate general concepts, and not to indicate required and/or necessary elements.

FIG. 1 illustrates an example power distribution environment with a plurality of meters serviced by two transformers.

FIG. 2 illustrates example structures and functionality of a meter within the example power distribution environment.

FIG. 3 illustrates example structures and functionality of a transformer, office, server, and/or computing device within the example power distribution environment.

FIG. 4 illustrates an example time-stamped voltage values database.

FIG. 5 illustrates an example correlation module for correlating time-stamped voltage values.

FIG. 6 illustrates an example graph showing multiple voltage differences of a voltage value associated with a meter and a voltage value associated with a transformer over a sequence of time-stamps.

FIG. 7 illustrates an example correlation database.

FIG. 8 illustrates an example mapping module.

FIG. 9 illustrates a first example map displaying a power line configuration of meters and transformers in a power distribution area.

FIG. 10 illustrates a second example map displaying a power line configuration of meters and transformers in a power distribution area.

FIG. 11 illustrates a first example method of determining and displaying a power distribution line configuration.

FIG. 12 illustrates a second example method of determining and displaying a power distribution line configuration.

### DETAILED DESCRIPTION

### Overview

The disclosure describes techniques for determining and displaying a power distribution line configuration for metering nodes and transformers within a power distribution environment. Determining which meters are connected to which transformers is particularly important in a smart electrical grid environment, and improves data utilization and electrical grid operation. For instance, determining the power distribution line configuration (or “topology”) may be used to determine which transformer/s to isolate (e.g., shut down power to) in order to perform repairs. Determining the power distribution line configuration may also be used to detect changes in the power distribution lines (e.g., due to damage or malicious activity).

In some examples, a computing device may receive time-stamped voltage values from multiple meters and transformers. The way in which these meters and transformers are connected may be unknown. In some examples, the computing device may determine that one or more meters have uploaded voltage data that shares a common time-stamp (i.e., represent measurements that occurred at substantially the same time) with one or more transformers. The computing device may determine that the voltage values of at least some of the meters that share a common time-stamp with a transformer correlate with the respective transformer. In some embodiments, the correlation may comprise subtracting the first time-stamped voltage value from the second time-stamped voltage value to determine a voltage difference. If the voltage difference falls within a predetermined threshold, then it may be determined that the meter is correlated to the transformer. In some examples, multiple voltage differences over time may be compared to the predetermined threshold to correlate the meter to the transformer.

In some embodiments, multiple correlations for multiple meters and transformers may be determined and stored in a correlation database. A mapping module may access the stored correlations and display them as a map on a display of a computing device. For instance, the meters and transformers may be presented on the map at locations that correspond with their actual physical locations. Lines may be displayed connecting each transformer to each meter that has been correlated to the respective transformer. In some examples, the correlations may be presented as a color-coding or shading of each displayed device. Other conventions may be used to indicate a meter-to-transformer connection, such as different shapes, symbols, sounds, patterns, etc., which may provide an intuitive visualization of the power line locations.

In some examples, a topology map or report of meter-to-transformer power distribution line configurations may be generated in response to a trigger. The trigger may comprise a power outage, a service call, a discrepancy with a previous correlation, or an elapsing of a predetermined amount of time. In some instances, the report may include an instruction to a repairman or other service personnel to service one of the meters and/or transformers. The systems and methods described herein may be useful for keeping a topology up-to-date, periodically or continuously. Furthermore, the systems and method may provide an improved visualization of where power lines are located so that the topology may be quickly and better understood.

### Illustrative Systems

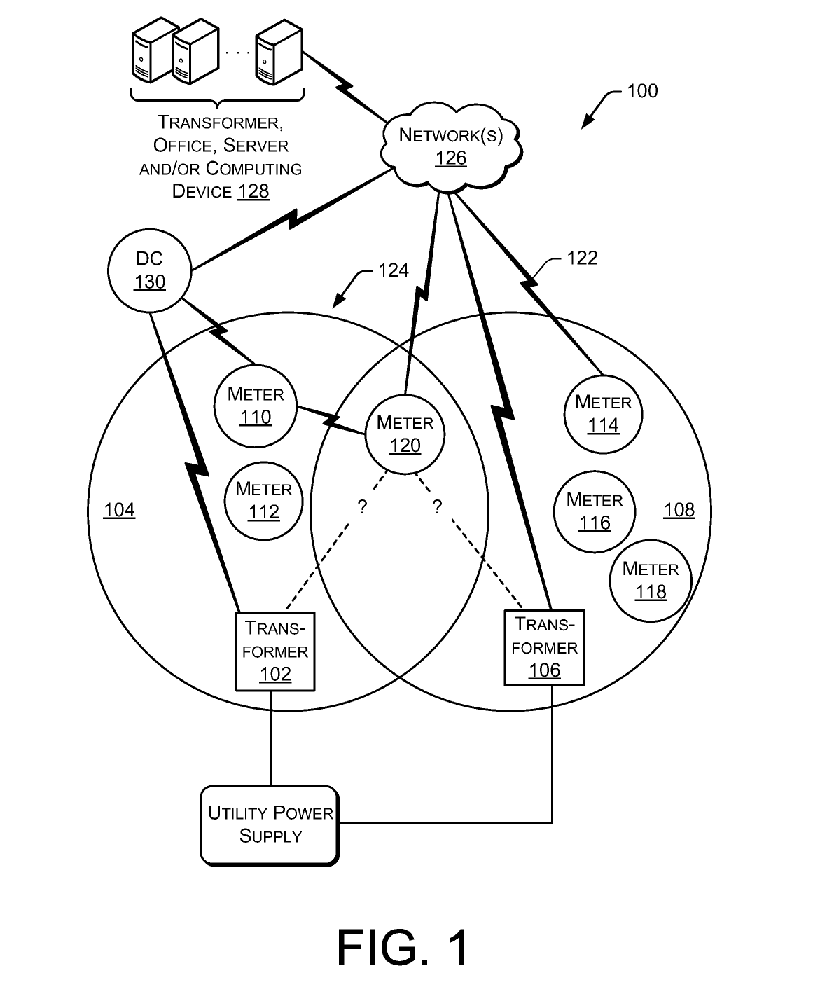

FIG. 1 is a block diagram showing an example power distribution environment 100 in which a first transformer 102 services a first power distribution area 104 and a second transformer 106 services a second power distribution area 108. A plurality of power utility metering nodes (hereafter referred to as “meters”) may be installed in one or both of the first and second power distribution areas 104 and/or 108. For instance, meters 110 and 112 may be located in the first power distribution area 104 and meters 114, 116, and 118 may be installed in the second power distribution area 108.

In some examples, meters of the power distribution environment 100 may receive utility power from transformers of the power distribution environment 100. For instance, meter 110 may receive a utility power from the first transformer 102 by a power line physically connecting a power terminal of the first transformer 102 to meter 110. For instance, the first transformer 102 may be installed on a telephone pole on a street and may receive power from a nearby or distant utility power station. The first transformer 102 may receive power from a substation via one or more medium voltage lines. Meter 110 may be installed on a house in a neighborhood proximate to the first transformer 102. Power lines may transmit a stepped-down AC voltage (e.g., 120 volts or 240 volts) from the first transformer 102 to the meter 110 so that power may be consumed and measured at the locations of the meter 110. In some examples, the power line may run overhead or the power lines may be buried below ground.

In some embodiments, if there is not an up-to-date and available record of power line configurations, then there may be more than one transformer that is possibly providing power to an installed meter 120. For instance, meter 120 may be at a location in both the first power distribution area 104 and the second power distribution area 108 due to an overlap of these power distribution areas. Therefore, the meter 120 could be receiving power from either the first transformer 102 or the second transformer 106. In some instances, there may be an installation record of which transformer the meter 120 was connected to during installation. However, a person trying to determine a configuration of power distribution lines may not have access to the installation records, which may be years, or even decades old and may be stored in an unknown location. Furthermore, the configuration may have changed (e.g., during an upgrade or repair) without an update of the installation records.

In some examples, the meters 110-120 may communicate data, updates, and/or other information by wireless (e.g., radio frequency—RF) or wired (e.g., power line communication—PLC) links 122, which may form a mesh network 124, a star network, or other network. The meters 110-120 may transmit data up- and downstream by one or more links and/or a backhaul network 126, such as the Internet or a private network. Accordingly, a transformer (e.g., 102, 106), office, server or computing device (hereafter referred to as “the server”) 128 may communicate with the meters 110-120 and/or the meters may communicate with themselves.

In some embodiments, such as in the case of a star network, the meters 110-120 may upload data to a data collector 130. The data collector 130 may comprise hardware (e.g., transceiver, memory, and/or processors) and software to receive, store, and/or retransmit the data uploaded from the meters 110-120. In some examples, the data collector 130 may be installed remotely from the meters 110-120. For instance, the data collector 130 may be installed on a telephone pole, or in a remote site equipment enclosure. In some embodiments, the data collector 130 may be constructed integral with one of the transformers 102 or 106 and/or the data collector 130 may be constructed integral with one of the meters 110-120.

In some examples, the meters 110-120 may upload data including data related to the consumption of utility power at the meters 110-120. For instance, the meters 110-120 may upload data with a time-stamp indicating a time at which the power was consumed, and a voltage or current value indicating the amount of electricity consumed at the time of the time-stamp. In some examples, the server 128 may maintain a clock for the devices downstream of the server 128. The data collector 130 may maintain the clock for the devices downstream from the data collector 130. In some examples, each device may maintain its own clock for determining the time-stamps. In some examples, one or more devices of the power distribution environment 100 may use time drift algorithms to maintain consistent clocks and time-stamps.

In some embodiments the meters 110-120 may upload data including location information. For instance, the meters 110-120 may collect and upload longitude and latitude coordinates determined by a Global Positioning System (GPS) module at the meters 110-120. In some examples, the meters 110-120 may obtain location information through other techniques, such as triangulation based on cell towers (in instances where the meters 110-120 have cellular capabilities), other triangulation methods, or the location information may be entered by an administrator prior to, during, or after installation.

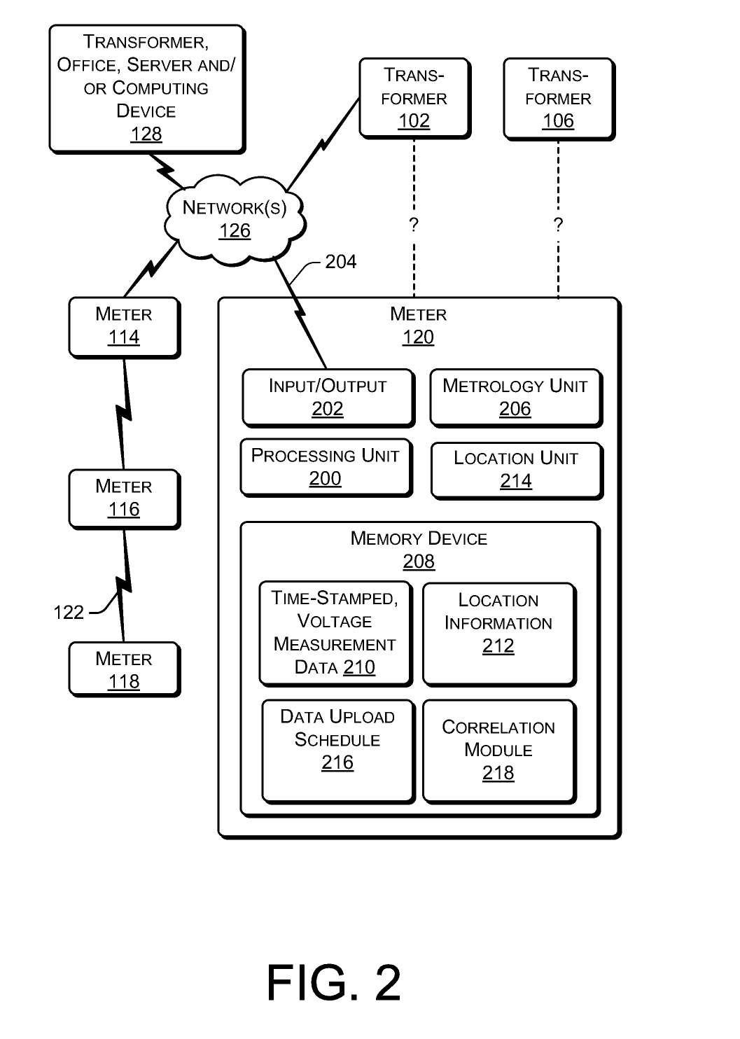

FIG. 2 is a block diagram showing example structure and functionality of the meter 120 within the example power distribution environment 100. The meter 120 is representative, though not determinative, of the structure of other meters 110-118. As discussed with regard to FIG. 1, meter 120 may have an unknown or unconfirmed power line configuration, connecting meter 120 to either the first transformer 102 or the second transformer 106. FIG. 2 illustrates various modules, which may be implemented by hardware, software, or a combination thereof.

In some embodiments, the meter 120 may comprise a processing unit 200. The processing unit may include hardware (e.g., processor, memory, and other circuits). For instance, the processing unit 200 may include a processor (e.g., general purpose microprocessor, CPU, GPU, etc.), application specific integrated circuit (ASIC) or other computing device configured to execute programs and/or perform logical or algorithmic actions. The processing unit 200 may communicate with an input/output unit 202, which may in turn communicate with other network devices over an RF link, power line communications (PLC) or other means 204.

In some examples, the meter 120 may comprise a metrology unit 206. The metrology unit 206 may be configured to measure voltage, current, and/or power consumption by a consumer/customer associated with the meter 120. Measurement data (e.g., voltage, current, and/or power consumption measurements) from the metrology unit 206 may be associated, or time-stamped, with times at which each measurement is made. Measurement data collected at the meter 120 may be stored in an appropriate data structure within a memory device 208.

The processing unit 200 may also communicate with the memory device 208 and/or other memory devices, which may contain programs, applications, data structures, or other information. For instance, the memory device 208 may store time-stamped voltage measurement data 210 generated by the metrology unit 206. The memory device 208 may comprise a computer-readable media, described in greater detail below in the “Illustrative Methods” section of this disclosure.

In some examples, the memory device 208 may store location information 212. The location information 212 may be associated with a physical location of the meter 120, such as a GPS coordinate location (e.g., longitude and latitude) of the meter 120. In some embodiments, the location information 212 may be collected or determined by a location unit 214 of the meter 120. For instance, the location unit 214 may comprise a GPS receiver in communication with a GPS satellite. In some examples, the location information 212 may be entered into the memory device 208 manually, prior to, during or after installation of the meter 120.

In some embodiments, the memory device 208 may store a data upload schedule 216. The data upload schedule 216 may include a list of designated times at which the meter 120 uploads data stored in the memory device 208 to a data collector, another meter, transformer, office, server, and/or other computing device. The upload schedule 216 may be received and stored at the meter 120 from a data collector, another meter, transformer, office, server, and/or other computing device.

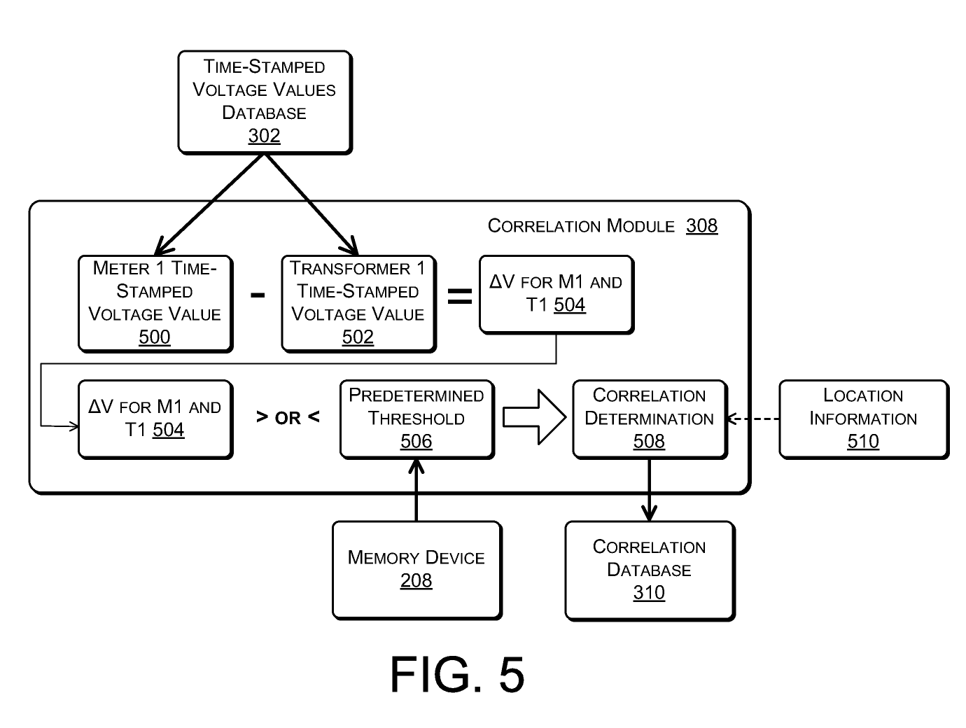

In some examples, the memory device 208 may include a correlation module 218. In other examples, the correlation module 218 may be stored at a data collector, another meter, transformer, office, server, and/or other computing device. The correlation module 218 is discussed in greater detail below with regard to FIG. 5.

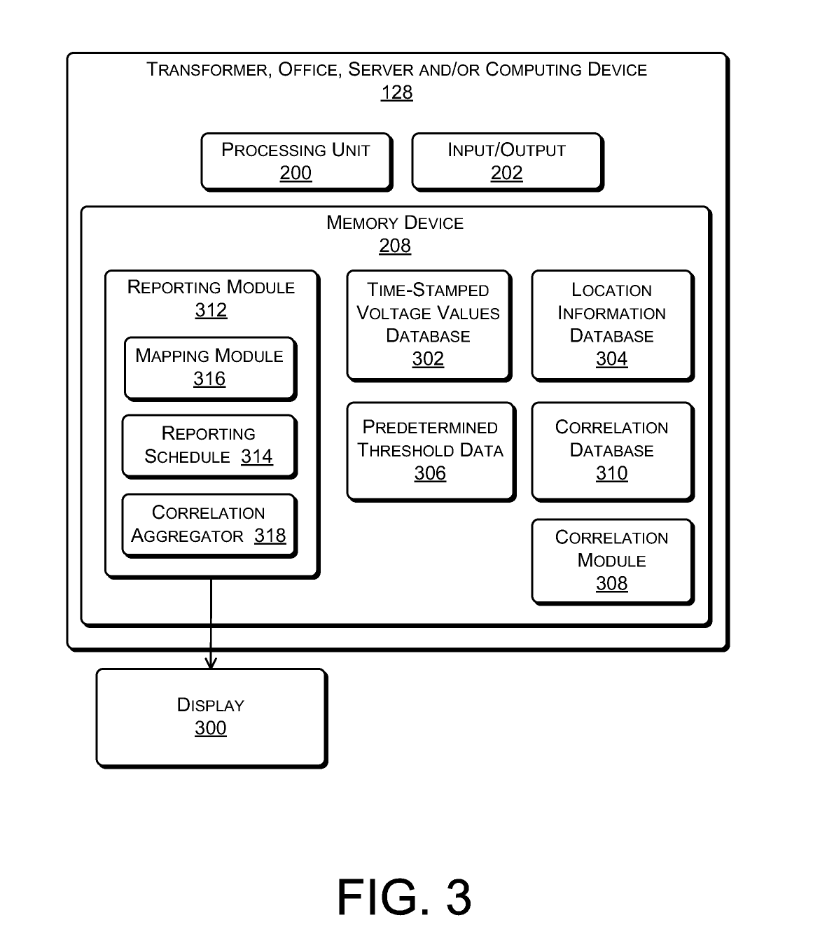

FIG. 3 is a block diagram showing example structure and functionality of the server 128 within the example power distribution environment 100. Although the server device 128 is herein referred to as “the server 128”, the structure and functionality of the server 128 may, in some examples, comprise a metering node, a transformer, a data collector, a central office, a server, a mobile device, other computing devices, and/or combinations thereof. For instance, the structure and functionality of the server 128 may be divided among different devices and may occur at multiple locations, or at a single location. In some examples, the server 128 may comprise a data center or multiple data centers coordinated together.

The server 128 may be configured to receive data from one or more of the meters 110-120, and from one or more of the transformers 102 and 106. The server 128 may be configured to perform a correlation of the data received from the meters 110-120 and transformers 102 and 106 to determine a power line configuration of the meters 110-120 and transformers 102 and 106. In some examples, the server 128 may be configured to display the determined power line configuration on a display 300 integral with or separate from the server 128.

In some examples, the server 128 may include a processing unit 200, input/output unit 202 and/or memory device 208, which may be as described with respect to meter 120 and FIG. 2. Furthermore, the modules illustrated in FIG. 3 may be implemented by hardware, software, or a combination thereof.

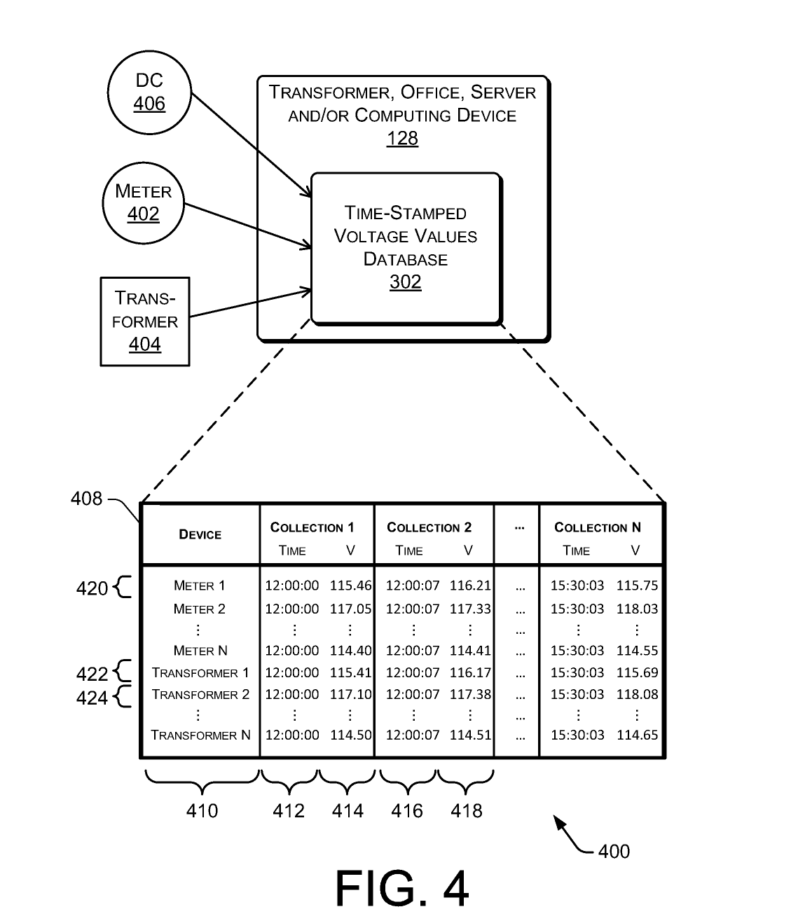

In some embodiments, the memory device 208 of the server 128 may include one or more applications, programs, databases, or other information. In some examples, the memory device 208 may include a time-stamped voltage values database 302. The time-stamped voltage values database 302 may store time-stamped voltage values associated with at least one of meters 110-120 and/or at least one of transformers 102 and 106. In some examples, the time-stamped voltage values may be received directly from one of the meters 110-120 or one of transformers 102 and 106, yet, in other examples, the time-stamped voltage values may be relayed to the server 128 through an intermediary device, such as the data collector 130 of FIG. 1 or another meter with relaying capabilities (such as in a mesh network). The time-stamped voltage database 302 is discussed in greater detail below with respect to FIG. 4.

In some examples, the memory device 208 may include a location information database 304. The location information database 304 may store information associated with the locations of meters 110-120 and/or transformers 102 and 106. For instance, the location information database 304 may store GPS coordinates of the meters 110-120 and/or the transformers 102 and 106. The location information database 304 may store street addresses associated with the meters 110-120 and/or transformers 102 and 106. In some examples, the location information database 304 may store relational location information of the meters 110-120 and/or transformers 102 and 106. For instance, relational location information associated with meter 110 may be stored as “50 meters west of transformer 102” or “Across the street from the Bank of America building”. The location information database 304 may store any other information which may be used to associate the meters 110-120 and/or transformers 102 and 106 with a physical location.

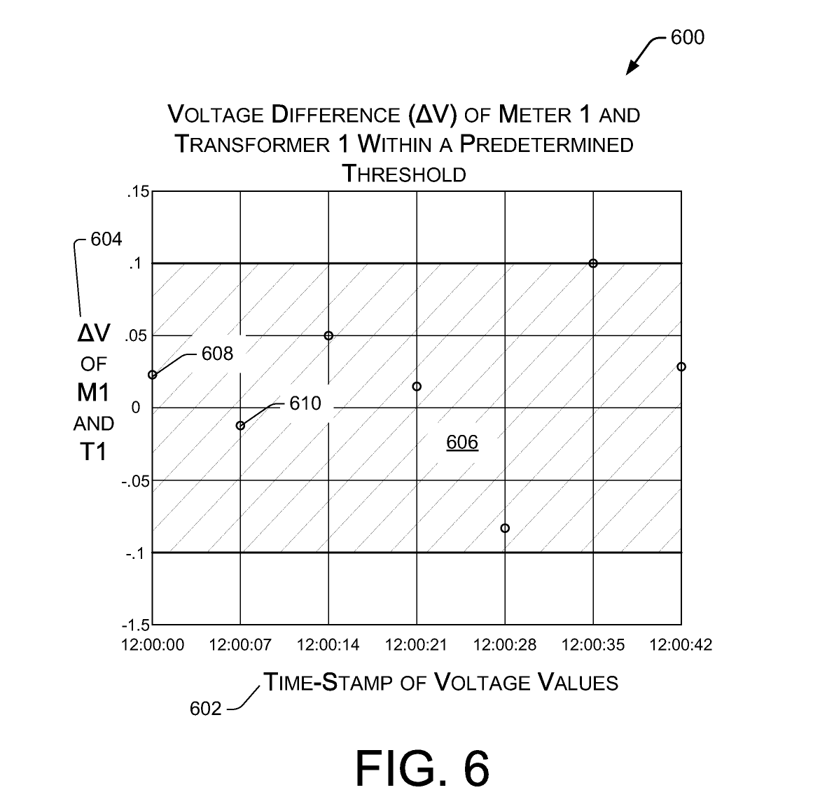

In some embodiments, the memory device 208 may include predetermined threshold data 306. The predetermined threshold data 306 may include values or a range of values that represent a predetermined acceptable difference of voltages in order to determine a correlation. The predetermined threshold data 306 may be received from a central office or another computing device, or the predetermined threshold data 306 may be stored in the server 128 during installation of the applications or programs into the memory device 208. In some examples, the predetermined threshold data 306 may remain constant over an extended time period of use, or the predetermined threshold data may be dynamic, in that it may change over time, if needed, to suit the power distribution system (which may change over time, as well). The predetermined threshold data 306 is discussed in greater detail below with respect to FIG. 6.

In some examples, the memory device 208 may include a correlation module 308. The correlation module 308 may access information from the time-stamped voltage values database 302, the predetermined threshold data 306 and/or the location information database 304 in order to determine a correlation of one device to another, or multiple devices to other multiple devices. For instance, if a difference between two time-stamped voltage values from the time-stamped voltage values database 302 is within a range from the predetermined threshold data 306, the devices associated with the two time-stamped voltage values may be determined to be correlated. In some examples, a correlation of two devices may indicate that the two devices are connected by a power distribution cable or line. The correlation module 308 is discussed in greater detail below with respect to FIG. 5.

In some embodiments, the memory device 208 may include a correlation database 310. The correlation database 310 may store information associated with the correlations determined by the correlation module 308. For instance, the correlation module 308 may determine a first configuration of power distribution lines for meters 110-120 and transformers 102 and 106. The first configuration may be stored in the correlation database 310. At a later time, the correlation module 308 may determine a second configuration of power distribution lines for meters 110-120 and transformers 102 and 106. The second configuration may be stored in the correlation database 310. By storing multiple configurations over time (which may be compared to each other) the correlation database may provide a history of configurations of the power distribution lines or changes to the configuration of the power distribution lines. In some embodiments, the correlation database 310 may be exported for consumption by external applications.

In some examples, the memory device 208 may include a reporting module 312. The reporting module 312 may access information from the correlation database 310 and the location information database 304 in order to generate and/or display a report. For instance, the reporting module 312 may comprise a reporting schedule 314, which may provide predetermined times at which to generate a report (e.g., hourly, daily, monthly, annually). In some instances, the times to generate a report stored in the reporting schedule 314 may depend on the purpose of the report and/or the intended reader of the report. In some examples, the reporting module 312 may generate a report not according to the reporting schedule 314, but rather in response to a trigger to generate a report. In some examples, the trigger to generate a report may comprise a power outage, a service call, a discrepancy from a previous correlation, a manual request, or an elapsing of a predetermined amount of time.

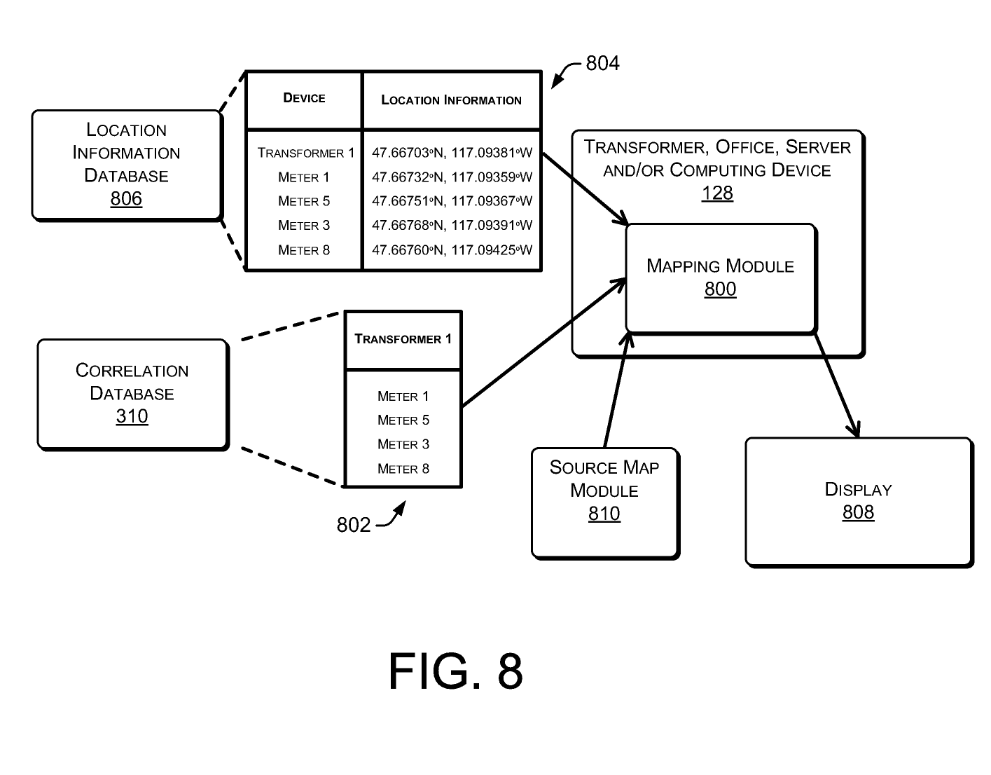

In some embodiments, the reporting module 312 may include a mapping module 316. The mapping module 316 may access reports generated by the reporting module 312 and display the reports on the display 300. In some examples, the mapping module 316 may interface with a source map software or module (e.g., Google Maps, Itron Analytics, Field Collection System, etc.) to integrate or overlay the report into the source map module. The mapping module 316 is discussed in greater detail below with respect to FIGS. 8-10.

In some examples, the reporting module 312 may comprise a correlation aggregator 318. The correlation aggregator 318 may aggregate multiple correlations from the correlation database 310 for reporting. For instance, the correlation aggregator 318 may consolidate correlations from multiple areas into a single geographic area for reporting. In some examples, the correlation aggregator 318 may consolidate correlation information from multiple correlation databases (from the same memory device 208 or from multiple memory devices). In some embodiments, the correlation aggregator 318 may consolidate multiple correlations for the same area and/or the same devices, but from different times, so that the reporting module 312 may report a change of the configuration of power distribution lines over time.

FIG. 4 is a block diagram illustrating the example time-stamped voltage values database 302, which may be stored in the memory device 208 of the server 128. In some embodiments, the time-stamped voltage values database 302 may receive and store time-stamped voltage values 400 associated with a meter 402 or a transformer 404 of a power distribution environment. In some instances, the time-stamped voltage values 400 may be received directly from the device (meter 402 or transformer 404) to which the time-stamped voltage values 400 are associated, or the time-stamped voltage values 400 may be received from an intermediary device, such as a data collector 406. The time-stamped voltage values 400 may be received and stored according to a predetermined schedule, such as an upload schedule of the meter 402, transformer 404, and/or data collector 406, or the time-stamped voltage values 400 may be received sporadically, or randomly, as the time-stamped voltage values 400 become available.

In some instances, the time-stamped voltage values 400 may be stored in a data structure, such as a spreadsheet (e.g., using comma-separated values) 408. The spreadsheet 408 may include a first column 410 listing each device for which a particular time-stamped voltage value is associated. The spreadsheet 408 may include a second column 412, which may list the times indicated by each of the time-stamps of the received voltage values. The spreadsheet 408 may include a third column 414, which may list the measured voltages associated with the devices listed in the first column 410 at the times listed in the second column 412.

In some examples, the measured voltages of the third column 414 may be derived from consumption data uploaded by the meter 402. For instance, the meter 402 may upload consumption data including time-stamped voltage values, current values, and/or power values for billing purposes. The time-stamped voltage values database 302 may access the uploaded consumption data and import select portions of the consumption data to the spreadsheet 408. In this way, the information used to determine correlations between devices may already be available from previously uploaded consumption data. In other examples, the meter 402, transformer 404, and/or data collector 406 may upload time-stamped voltage values not associated with consumptions data, with the primary purpose of determining correlations between devices.

In some examples, the spreadsheet 408 may comprise fourth and fifth columns 416 and 418 including second times associated with second measured voltage values. In fact, the spreadsheet 408 may comprise any N number of columns to represent any number of received time-stamped voltage values 400. In some embodiments, the spreadsheet 408 may include a first row 420 representing a first metering device. The spreadsheet 408 may include any N number of rows representing any number of metering devices. In some examples, the spreadsheet 408 may comprise a first transformer row 422, a second transformer row 424, or any N number of transformer rows representing transformers for which the spreadsheet 408 may store time-stamped voltage values 400.

Although FIG. 4 illustrates the spreadsheet 408 as one example data structure which may store time-stamped voltage values 400 for later access, the time-stamped voltage values 400 may be stored in other data structures. For instance, the time-stamped voltage values 400 may be stored as a list, a diagram, a flow chart, or a map. The time-stamped voltage values 400 may be stored in multiple data structures. For instance, the memory device 208 may store a database of time-stamped voltage values corresponding to meters and another database of time-stamped voltage values corresponding to transformers. There are many configurations of data structure storage that may be implemented to retrievably store the time-stamped voltage values 400 in the time-stamped voltage values database 302.

FIG. 5 is a block diagram illustrating the example correlation module 308 which may be stored in the memory device 208 of the server 128. The correlation module 308 may access a first time-stamped voltage value 500 associated with a first meter and a second time-stamped voltage value 502 associated with a first transformer. In some examples, first and second time-stamped voltage values 500 and 502 may be accessed from the time-stamped voltage values database 302 stored in the memory device 208, as described in FIG. 4. In other examples, the first and second time-stamped voltage values 500 and 502 may be accessed from other sources, such as another memory device separate from memory device 208 or directly from the meter or transformer associated with the first and second time-stamped voltage values 500 and 502.

In some embodiments, the correlation module 308 may calculate a voltage difference (ΔV) 504 between the first and second time-stamped voltage values 500 and 502. The ΔV 504 may be compared to a predetermined threshold 506. For instance, the correlation module 308 may determine if the ΔV 504 is greater than or less than the predetermined threshold 506. In some examples, the predetermined threshold 506 may be stored in and accessed from the memory device 208. Based on the comparison of the ΔV 504 to the predetermined threshold, a correlation determination 508 may be made. For instance, if the ΔV 504 is less than the predetermined threshold 506, it may be determined that the first meter and the first transformer are correlated. Correlating the first meter to the first transformer may indicate that the first meter is connected to the first transformer by a power distribution line and, thus, the first meter receives a utility power from the first transformer. If the ΔV 504 is greater than the predetermined threshold 506, it may be determined that the first meter is not correlated to the first transformer and, thus, the first meter is not connected to the first transformer by a power distribution line.

In some embodiments, the determined correlation 508 may be stored in the correlation database 310 for later access. In some examples, location information 510 related to the first meter and/or the first transformer may be used in determining a correlation. For instance, if the location information 510 of the first meter and the first transformer indicates that the first meter and the first transformer are located a large distance apart, such that it would be impossible for the first meter to receive power from the first transformer, then the correlation module 308 may determine that the first meter and the first transformer are not correlated, even though the ΔV 504 may be less than the predetermined threshold 506.

In some examples, a correlation based on a single ΔV 504 may be considered a “weak” correlation. Over time, as more ΔVs 504 are calculated and incorporated into the correlation, the correlation may become a “stronger” correlation, or the correlation may “fall apart” (e.g., become so weak that it is determined that the devices are not correlated). The “strength” of the correlation may correspond to a confidence interval, with a “stronger” correlation having a higher confidence level and a “weaker” correlation having a lower confidence level.

In some embodiments, the correlation module 308 may determine multiple correlations for multiple devices. For instance, the first time-stamped voltage value 500 may correspond to any of the meters in the first and second power distribution areas 104 108 and the second time-stamped voltage value 502 may correspond to any of the transformers in the first and second power distribution areas 104 and 108. In some examples, both the first and second time-stamped voltage values 500 and 502 may be received from meters or, in other examples, from transformers. Multiple correlations of multiple devices in a power distribution area may be determined and stored in the correlation database 310. Because each correlation indicates the configuration of a power line between devices, determining and storing all of the correlations of the devices in a power distribution area may determine the power line configuration for all of the devices in the power distribution area.

FIG. 6 shows an example graph 600 illustrating an example of multiple voltage differences (ΔV) for a meter (M1) and a transformer (T1) of a power distribution area. In the graph 600, the x-axis 602 represents a sequence of time-stamps of the received voltage values corresponding to M1 and T1. The y-axis 604 represents a range of potential voltage differences calculated by subtracting a voltage value of M1 from a voltage value of T1. The shaded area 606 represents an example predetermined threshold range between −0.1 volts and 0.1 volts.

By way of example, FIG. 6 shows a first ΔV 608 calculated at a time 12:00:00. The voltage values of M1 and T1 used to calculate ΔV 608 were determined to share a common time-stamp of 12:00:00. The first ΔV 608 indicates a voltage difference of about 0.023V, well within the predetermined threshold range. At 12:00:07, a second ΔV 610 is calculated to be about −0.018 and is graphed in the shaded area 606, indicating the second ΔV 610 is also within the predetermined threshold range. In fact, all of the ΔVs illustrated in the graph 600 are within the predetermined threshold range, and therefore the correlation module 308 would determine that M1 and T1 are correlated.

In some embodiments, multiple ΔVs of M1 and T1 for multiple times may be calculated and compared to the predetermined threshold. The correlation module 308 may determine a confidence interval of the correlation based, at least in part, on a percentage of ΔVs within the predetermined threshold range. The predetermined threshold range of FIG. 6 is shown to have an order of magnitude of 0.1 Volts. In some examples, the predetermined threshold range may have a smaller order of magnitude, such as an order of magnitude of 0.01 Volts, which indicates a higher degree of precision in the voltage measurements. The predetermined threshold range may have a greater order of magnitude, such as 1 Volt, which indicates a lower degree of precision in the voltage measurements. In some embodiments, the correlation module 308 may require fewer ΔVs to determine a correlation of M1 to T1 if the predetermined threshold has a high precision. Highly precise measurements may require fewer ΔVs whereas less precise measurements may require more ΔVs, in order to determine a correlation within an acceptable confidence interval. In some examples, the predetermined threshold range may be −4 to 4 Volts, −3 to 3 Volts, −2 to 2 Volts, −1 to 1 Volts, −0.9 to 0.9 Volts, −0.8 to 0.8 Volts, −0.7 to 0.7 Volts, −0.6 to 0.6 Volts, −0.5 to 0.5 Volts, −0.4 to 0.4 Volts, −0.3 to 0.3 Volts, −0.2 to 0.2 Volts, or any other ranges that provide adequate precision (wherein “adequate precision” may be based on the number of ΔVs calculated).

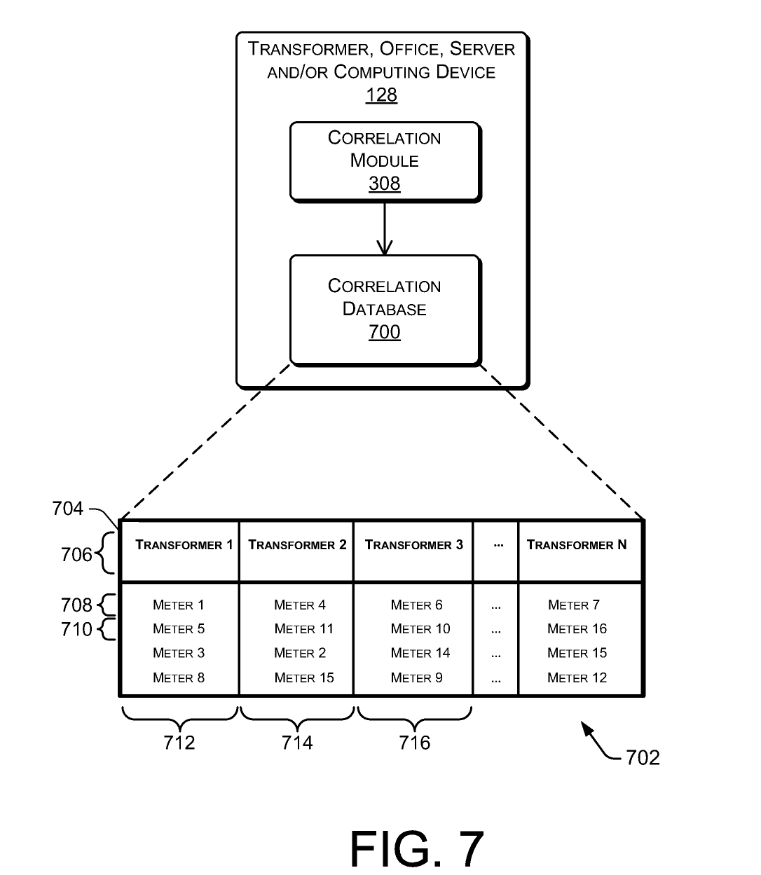

FIG. 7 is a block diagram illustrating an example correlation database 700, which may be stored in the memory device 208 of the server 128. In some embodiments, the correlation database 700 may receive and store correlation information 702 from the correlation module 308, as described above with respect to FIGS. 5 and 6. In some examples, the correlation database 700 may receive and store correlation information 702 from other databases or other correlation modules, integral to or separate from the memory device 208.

In some embodiments, the correlation database 700 may store correlation information 702 representing the correlation of multiple devices to other multiple devices in a power distribution area. For instance, the correlation information 702 may be stored in a data structure, such as a spreadsheet 704, or in other data structures, such as a list, a diagram, a flow chart, a map, multiple data structures, and/or combinations thereof. In some examples, the spreadsheet 704 may illustrate a “tree-structure” of correlation information.

In some embodiments the spreadsheet 704 may comprise a header row 706. The header row 706 may include devices to which multiple other devices are correlated. For instance, the header row 706 may list all of the transformers in a power distribution area. In some examples, the header row 706 may list meters, or a combination of meters and transformers. The spreadsheet 704 may comprise a second row 708, a third row 710, or any N number of other rows, listing devices correlated to the devices listed in the header row 706.

In some embodiments, the header row 706 may list only meter devices. For instance, transformer data may not be available and the only correlations calculated may be correlations of meters to other meters. In some examples, where meters are only correlated to other meters, the header row 706 may list reference numbers to groupings of the correlated meters.

In some examples, the spreadsheet 704 may include a first column 712. The first column 712 may list a first transformer in the header row 706 and all of the meters that have been correlated to the first transformer in the rows below the header row 706. The spreadsheet 704 may include a second column 714 listing a second transformer and all of the devices correlated to the second transformer. The spreadsheet may include a third column 716, a fourth column, or any N number of columns, each column corresponding to a transformer that has been correlated to other devices.

FIG. 8 is a block diagram illustrating a mapping module 800, which may be stored in the memory device 208 of the server 128. The mapping module 800 may provide a method for displaying correlation information 802 from the correlation database 310, and location information 804 from the location information database 806, on a display 808. The display 808 may be integral with, proximate to, or remote from the server 128.

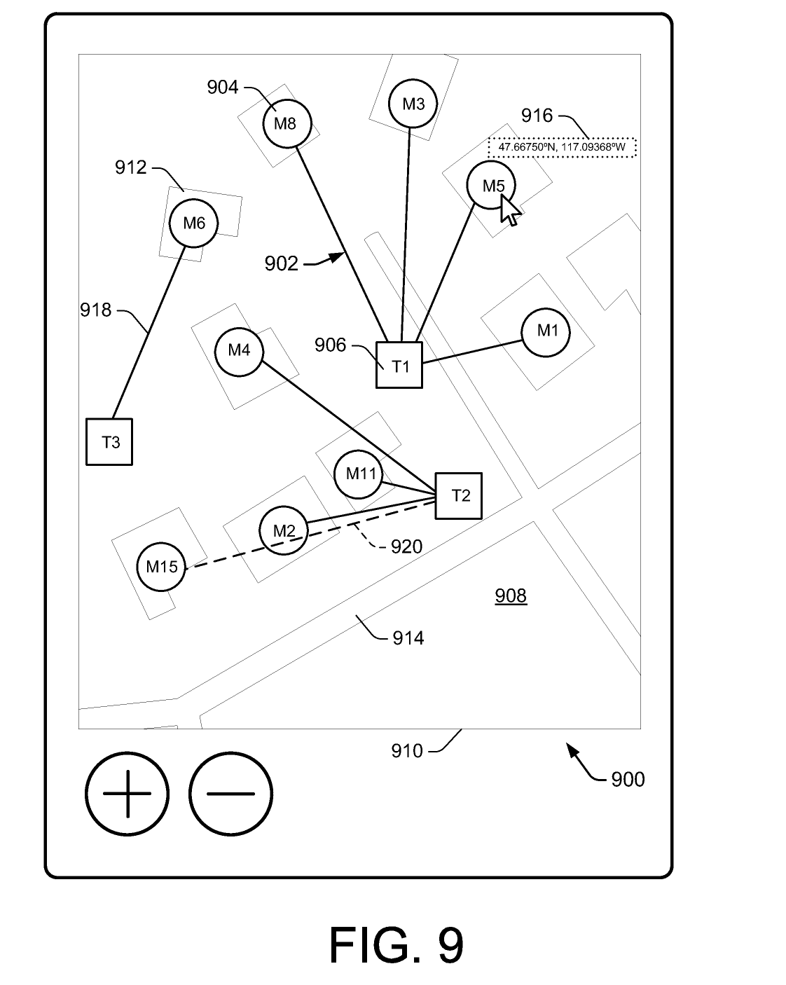

In some examples, the mapping module 800 may access correlation information 802 indicating which meters are correlated to which transformers, or which meters are correlated to other meters. For instance, FIG. 8 illustrates an example where transformer 1 (T1) has been correlated to meter 1 (M1), meter 5 (M5), meter 3 (M3) and meter 8 (M8). These correlations may have been determined and stored in the correlation database 310 using any of the previously disclosed methods. The mapping module 800 may access the location information 804 from the location information database 806. For instance, the location information 804 may include a list of devices (both meters and transformers) and location data associated with each of the devices. In the example illustrated in FIG. 8, the location information 804 comprises GPS coordinates, however, the location information 804 could comprise any information representative of the physical locations of the listed devices. In some examples, the mapping module may access a source map module 810 from a third party, as discussed in greater detail below with respect to FIG. 9.

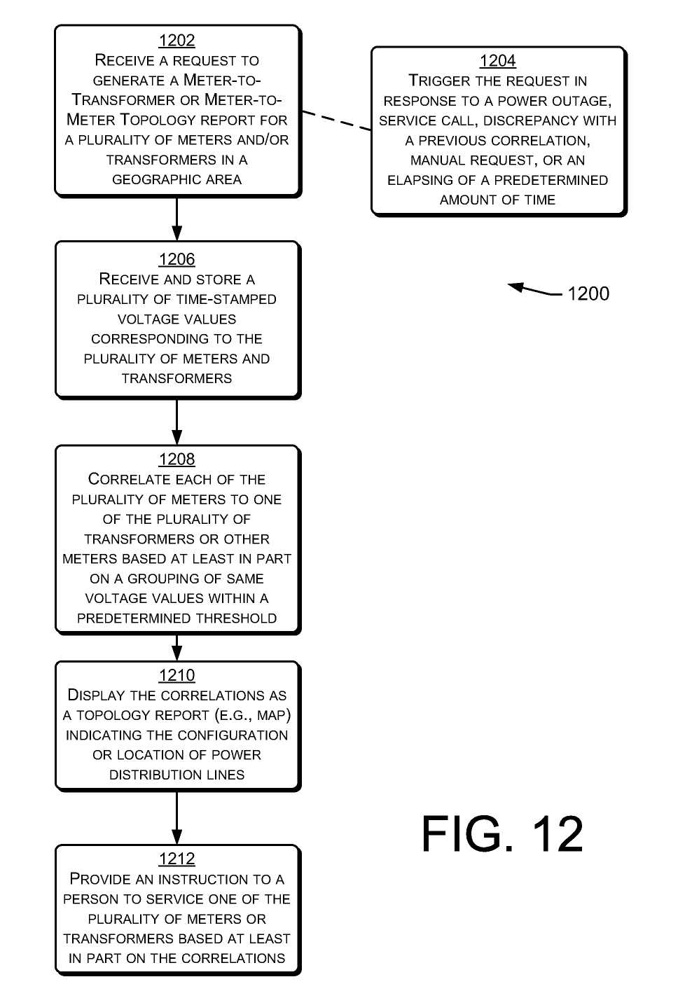

In some embodiments, the mapping module 800 may access the location information 804 after accessing the correlation information 802, because the correlation information 802 may indicate which devices are to be mapped, which in turn may determine the locations to be mapped. In some examples, the mapping module 800 may access the correlation information 802 after accessing the location information 804 because the location information 802 may indicate a geography or power distribution area to be mapped, which in turn may determine the devices to be mapped. Whether the correlation information 802 or the location information 804 is accessed first may depend on the trigger or purpose to generate a report and/or a map, discussed below with regard to FIG. 12.

FIG. 9 illustrates a first example map 900 displaying a power line configuration 902 of meters 904 and transformers 906 of a power distribution area 908 on a display 910. In some examples the display 910 may comprise the display of a mobile device, such as a mobile tool carried by a technician, repairman, or installer or the display of a smart phone or tablet device. In some examples the display 910 may comprise the display of a terminal at a central office or monitoring site.

In some embodiments, the map 900 may include a source map module, which may be generated by the server 128 or by a third party. For instance, the source map module may comprise a Google Maps module, an Itron Analytics module, a Field Collection System module, or any other source map modules that may be compatible with plug-ins or overlays. In some examples, the mapping module 800 may display the map 900, by interfacing with the source map module and overlaying the meters 904 and the transformers 906 at their respective locations on the source map module.

In some examples, the source map module may display houses 912 and roads 914, and may include the ability to zoom in and out to enlarge or shrink the physical area being mapped. The mapping module 800 may graphically present the meters 904 on the map 900 at locations that correspond with the location information 802 accessed by the mapping module 800. For instance, a meter M5 may be associated with the location information 916. By way of example, the location information 916 may comprise the GPS coordinates 47.66750° N, 117.09368° W. In some examples, the location information 802 being displayed may comprise a utilities service point identifier, such as a meter number, transformer number, endpoint number, and/or account number. The source map module may determine a location within the source map module being displayed that corresponds to the location information 916, and display the meter M5 at this location within the source map module.

In some examples, the mapping module 800 may determine the physical area being displayed, and then present every meter (e.g., as shown in FIG. 9, M1, M2, M3, M4, M5, M6, M8, M11, and M15) and/or each transformer (e.g., as shown in FIG. 9, T1, T2, and T3) within the displayed physical area at the locations corresponding to the location information associated with each meter and/or every transformer. For instance, the mapping module 800 may determine which devices to display by first determining a range of GPS coordinates being displayed (which may be determined by the level of zoom), and then comparing the determined range of GPS coordinates to the location information 804 in the location information database 806. Devices with location information within the determined range may be displayed and devices with location information outside the determined range may be omitted from being displayed. The mapping module 800 may repeat this process each time the physical area being displayed is changed (e.g., zoomed in, zoomed out, or scrolled).

In some embodiments the mapping module 800 may display the power line configuration of the displayed meters 904 and the displayed transformers 906. Based on the correlation information 802 from the correlation module 310, the mapping module 800 may show that each transformer being displayed is connected to a sub-group of meters being displayed. In some examples, the mapping module 800 may show a correlation of meters to other meters. By way of example, the mapping module 800 may display transformer T1 as being connected to meters M1, M5, M3, and M8, transformer T2 as being connected to meters M11, M2, M4, and M15, and transformer T3 as being connected to meter M6. For instance, meters M1, M5, M3, and M8 may have been correlated to each other by the correlation module 308. If it is known that any of meters M1, M5, M3, or M8 are connected to T1, than the mapping module may display the rest of the correlated meters M1, M5, M3, and/or M8 as being correlated to T1, as well. In some examples meters may be correlated to each other without correlating any of the meters to a transformer.

In some embodiments, the connections between transformers and meters may be shown on the display as a line 918. The line 918 may represent a power distribution cable physically connecting a transformer (e.g., T3) to a meter (e.g., M6) in order to distribute power to the meter. In some examples, the mapping module 800 may display every power distribution cable connecting each of the devices being displayed. The mapping module 800 may display the entire power line configuration of the physical area being displayed.

In some embodiments, the mapping module 800 may present data, such as voltage or consumption data, a latest voltage or consumption read, and/or the location information 804 (e.g., GPS coordinates, addresses, etc.), on the display 910. For instance, the location information 804 of each meter 904 and transformer 906 being displayed may comprise data embedded in an area of the display 910 proximate to the meter 904 and/or transformer 906 being displayed. The mapping module 800 may display the embedded location information 804 when a user activates the embedded data (e.g., by pausing a cursor over or clicking on a meter or transformer).

In some examples, the mapping module 800 may access the correlation aggregator 318 in order to display a change of the power line configuration 902 over time. For instance, if a connection between a meter (e.g., M15) and a transformer (T2) was determined by a first correlation, but then a second correlation determines the meter and the transformer are not correlated, the change in correlations may be displayed (e.g., by a dashed line 920). In some examples, the change in correlations may be displayed via a time slider bar that may “rewind” time, or step forward/backward in time to show connections of the past. Displaying changes in correlations may provide the ability for an operator to base future adjustment plans on past adjustment history presented in a mapped format.

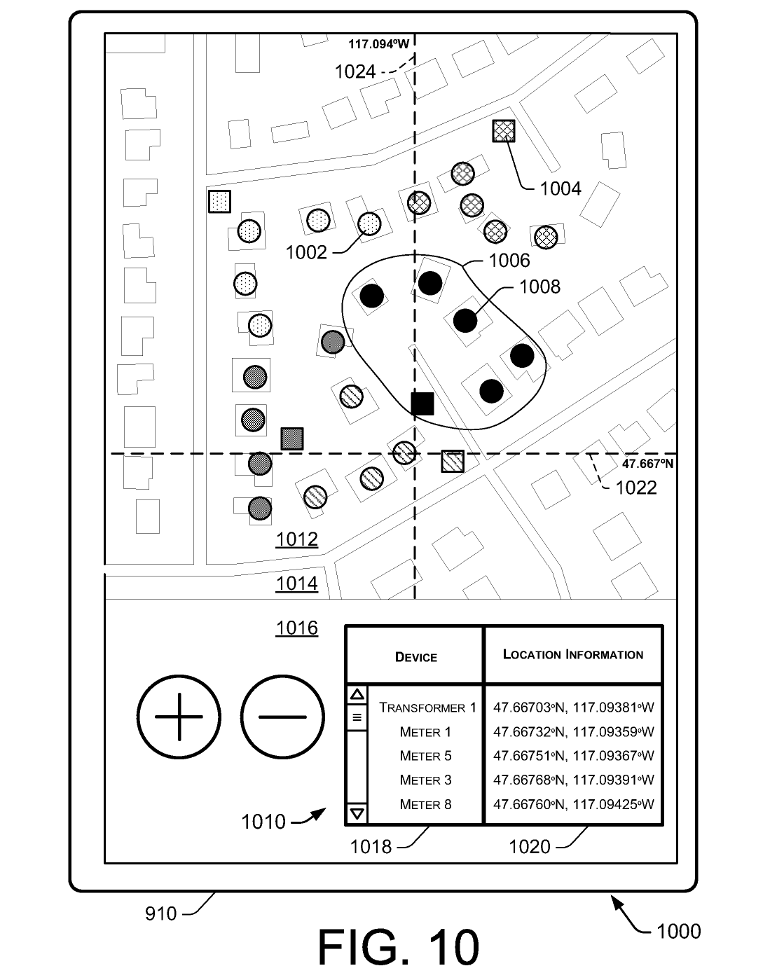

FIG. 10 illustrates a second example map 1000 showing a power line configuration of a plurality of meters connected to a plurality of transformers, which may be displayed on the display 910 by the mapping module 800. The second example map 1000 may include any of the features discussed above with respect to the first example map 900. In some examples, the meters may be denoted by a first shape 1002 and the transformers may be denoted by a second shape 1004. Although FIG. 10 shows the first shape 1002 as a circle and the second shape 1004 as a square, the first and second shapes 1002 and 1004 may comprise any shape (e.g., circle, square, triangle, polygon, or irregular shape).

In some embodiments, the mapping module 800 may display the power line configuration on the map 1000 by altering an appearance of each of the devices being displayed as a shape 1002 or 1004. For instance, a shading or fill of the shapes 1002 and 1004 may be changed to indicate which transformer each meter is connected to by a power distribution cable. By way of example, FIG. 10 shows five transformers correlated to 19 meters. The correlations are displayed by matching the shading of the meters (e.g., circles) to the shading of the transformer (e.g., square) to which the meters are correlated. For instance, a sub-group of meters and a transformer 1006 are shown with a solid black shading 1008. Because the meters of the sub-group 1006 have the same solid black shading 1008 as the transformer of the sub-group, they may be connected by power distribution lines.

In some embodiments, the mapping module 800 may display may present data, such as voltage or consumption data, a latest voltage or consumption read, and/or the location information 1010 (e.g., GPS coordinates, addresses, etc.), on the display 900 outside of a displayed physical area 1012. For instance the display 910 may have a portion 1014 designated for displaying the physical area 1012 and a portion 1016 designated for displaying other information, such as the location information 1010. In some embodiments, the location information 1010 may be displayed as a scrollable list, with devices in a first column 1018 and location data (e.g., GPS coordinates) in a second column 1020. In some examples, general location information, such as a line of latitude 1022 and/or a line of longitude 1024 may be displayed on the portion 1014 of the display showing the physical area 1012, such that a user may reference the general location information on the physical map while viewing the location information 1010, and vice versa.

### Illustrative Methods

In some examples of the techniques discusses herein, the methods of operation may be performed by one or more application specific integrated circuits (ASIC) or may be performed by a general purpose processor utilizing software defined in computer readable media. In the examples and techniques discussed herein, the memory device 208 may comprise computer-readable media and may take the form of volatile memory, such as random access memory (RAM) and/or non-volatile memory, such as read only memory (ROM) or flash RAM. Computer-readable media devices include volatile and non-volatile, removable and non-removable media implemented in any method or technology for storage of information such as computer-readable instructions, data structures, program modules, or other data for execution by one or more processors of a computing device. Examples of computer-readable media include, but are not limited to, phase change memory (PRAM), static random-access memory (SRAM), dynamic random-access memory (DRAM), other types of random access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transitory medium that can be used to store information for access by a computing device.

As defined herein, computer-readable media does not include transitory media, such as modulated data signals and carrier waves, and/or signals.

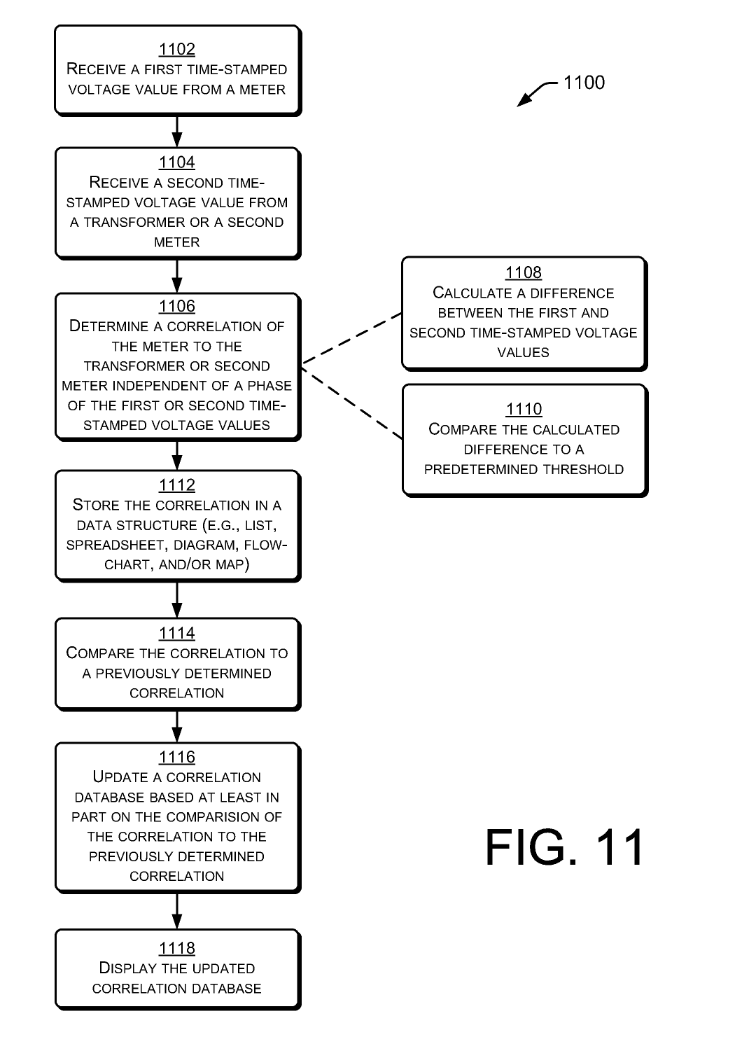

FIG. 11 is a flow diagram illustrating an example method 1100 of determining and displaying a power distribution line configuration. For convenience, the method 1100 will be described with reference to the systems and features illustrated in FIGS. 1-10, but the method 1100 is not limited to use with these systems and features. While FIG. 11 illustrates an example order, in some instances, the described operations in this and all other methods described herein may be performed in other orders and/or in parallel. Further, some operations of the method 1100 may be omitted, repeated, and/or combined.

In some examples, the method 1100 may begin with operation 1102, where a first time-stamped voltage value may be received from a meter. The first time-stamped voltage value may comprise a value indicating a utility power voltage received at the meter for power consumption at the location of the meter. The time-stamp of the first voltage value may indicate a time at which the voltage value was measured and/or the time at which power was consumed at the meter. As noted above, the time-stamped voltage value may be parsed from other data being uploaded by the meter for other uses, such as measuring power consumption (e.g., for billing purposes).

In some embodiments, the method 1100 may include operation 1104, where a second time-stamped voltage value may be received from a transformer or a second meter. The second time-stamped voltage value may comprise a value indicating a utility power voltage being distributed from the transformer, for example, to a plurality of utility meters in a power distribution area of the transformer. The time-stamp of the second voltage value may indicate a time at which the voltage value was measured.

In some examples, the method 1100 may include operation 1106, where a correlation of the meter to the transformer is determined. In some examples, operation 1106 may include steps that provide a determination without requiring any information regarding a phase of the first or second time-stamped voltages. For instance, operation 1106 may include operation 1108, where a difference is calculated between the first and second time-stamped voltage values. Operation 1106 may include operation 1110, where the difference is compared to a predetermined threshold. In some examples, an absolute value of the difference may be calculated before comparing the difference to the predetermined threshold. In other examples, the difference may comprise a positive or negative value, and the predetermined threshold may comprise a range with positive and negative ends.

In some embodiments, the method 1100 may include operation 1112 where the correlation is stored in a data structure, such as a list, a spreadsheet, a diagram, a flow chart, and/or a map. In some examples, the correlation may be stored in a memory such that is accessible by other executable programs. The correlation may be stored for an indefinite amount of time (for instance, to create a history of correlations), or the correlation may be deleted after a predetermined amount of time has elapsed.

In some examples, the method 1100 may include operation 1114, where the stored correlation is compared to a previously determined correlation. For instance, a record of previous correlations indicating that the meter and the transformer were previously not correlated may be stored. The record of previous correlations may be compared to the correlation of step 1106 to determine if there has been a change in the correlation status of the meter to the transformer. In some examples, a change in correlation status of the meter to the transformer may indicate a change in power line configurations of the meter to the transformer.

In some embodiments, the method 1100 may include operation 1116, where a correlation database is updated based, at least in part, on the comparison of the correlation to the previously determined correlation. For instance, the correlation database may have read-write functionality. If the comparison determined a change in correlations has occurred, an executable program may write over a portion of the database to record the change in correlation.

In some examples, the method 1100 may include operation 1118, where the updated correlation database is displayed. For instance, the correlation database may be converted to a graphical form to be presented on a graphic user interface. In some examples, the correlation database may be presented as a map on the display of a computing device. The update to the correlation database may be presented to show the change in correlation over time (e.g., by using a dashed line instead of a bold line, by using a different color, by adding text indicating a change has occurred, or by a historical time “slider”).

FIG. 12 is a flow diagram illustrating an example method 1200 of determining and displaying a power distribution line configuration. For convenience, the method 1200 will be described with reference to the systems and features illustrated in FIGS. 1-10, but the method 1200 is not limited to use with these systems and features. While FIG. 12 illustrates an example order, in some instances, the described operations in this and all other methods described herein may be performed in other orders and/or in parallel. Further, some operations of the method 1200 may be omitted, repeated, and/or combined.

In some examples, the method 1200 may begin with operation 1202, where a request to generate a meter-to-transformer or meter-to-meter topology report for a plurality of meters and/or transformers in a geographic area is received. In some examples, the requested topology report is a report indicating which meters are receiving power distribution lines from which transformers. In some examples, the requested topology report may be independent of or unrelated to a communication network or data uploading configuration of the meters and transformers in the geographic area. In some embodiments, the request to generate a report may be triggered 1204 in response to a power outage, a service call, a discrepancy with a previous correlation, a manual request, or an elapsing of a predetermined amount of time.

In some embodiments, the method 1200 may include operation 1206, where a plurality of time-stamped voltage values corresponding to the plurality of meters and transformers are received and stored. In some examples, a portion of the plurality of time-stamped voltage values may have been accumulated over time, prior to operation 1202, and stored in a memory device. In some examples, a portion of the plurality of time-stamped voltage values may be received and stored in response to the request received in operation 1202. In fact, the request of operation 1202 may trigger a request to the devices in the geographic area to record a voltage reading at an exact point in time, and to send the recorded voltage reading, i.e., “on-demand”.

In some examples, the method 1200 may include operation 1208, where each of the plurality of meters is correlated to one of the plurality of transformers based, at least in part, on a grouping of same voltage values within a predetermined threshold. For instance, a list may be generated wherein each column of the list constitutes a group of devices (meters and transformers) that share a same voltage value within a predetermined threshold for a common time-stamp. In some embodiments, a meter or a transformer may not share a same voltage with any other devices, in which case the meter or transformer will comprise a group of one device.

In some embodiments, the method 1200 may include operation 1210, where the correlations are displayed as a topology report, such as a map, indicating a configuration or location of power distribution lines. For instance, the map may display meters and transformers at locations on the map that correspond to their physical locations. The map may display lines connecting each meter to the transformer or to other meters that have been correlated to the meter. The map may display the meters and transformers as shapes with color-coding or shading indicating which meters are connected to which transformers. The displayed correlation may represent the approximate locations of physical power distribution cables connecting the meters to the transformers.

In some embodiments, the method 1200 may include operation 1212, where an instruction is provided to a person to service one of the plurality of meters or transformers based, at least in part, on the correlations. In some examples, the instruction may be included in the topology report. For instance, the topology report may indicate a meter that is not connected to any transformers, which may implicitly provide an instruction to service the meter because the meter has been damaged. The topology report may include explicit instructions, such as a blinking indicator or notification showing a transformer or meter that is not connected to other devices or has undergone a change in connections. In some embodiments, the instruction may be separate from the topology report, such as a text message to a service personnel including a street address of a meter that is not correlated to transformer.

### CONCLUSION

Although this disclosure uses language specific to structural features and/or methodological acts, it is to be understood that the scope of the disclosure is not necessarily limited to the specific features or acts described. Rather, the specific features and acts are disclosed as illustrative forms of implementation.

What is claimed is:

1. A method comprising:
receiving a first voltage value measured at a metering node of a power distribution system;
receiving a second voltage value measured at a transformer of the power distribution system;
calculating a correlation between the first voltage value and the second voltage value; and
determining if the metering node is connected to the transformer by a power distribution line, based at least in part on the correlation.

2. The method of claim 1, wherein the first voltage value is associated with a first time-stamp and the second voltage value is associated with a second time-stamp, the first and second time-stamps representing a substantially same time.

3. The method of claim 1, further comprising receiving location information associated with the metering node, wherein the determining is based at least in part on the location information.

4. The method of claim 1, wherein the calculating the correlation comprises calculating a difference between the first voltage value and the second voltage value and determining that the difference is within a predetermined threshold.

5. The method of claim 4, wherein the predetermined threshold comprises an order of magnitude of 1 volt.

6. The method of claim 1, wherein, prior to the calculating, the first and second voltage values are stored in a memory remote from the transformer and the metering node.

7. The method of claim 1, wherein the first voltage value is derived from received metering data.

8. The method of claim 1, wherein the first voltage value comprises a representation of a power distribution voltage provided to the metering node.

9. The method of claim 1, wherein the calculating the correlation comprises a calculation independent of a phase of the first or second voltage values.

10. A method comprising:
receiving a plurality of time-stamped voltage values, each of the time-stamped voltage values corresponding to one of a plurality of metering nodes or one of a plurality of transformers;
storing the plurality of time-stamped voltage values in a memory;
calculating, for a subset of the plurality of time-stamped voltage values that share a common time-stamp, a correlation; and
determining which of each of the plurality of metering nodes are connected to which of each of the plurality of transformers by a power distribution line, based at least in part on the correlation.

11. The method of claim 10, wherein the calculating comprises determining if the subset of time-stamped voltage values have a substantially same voltage value by comparing a difference of each of the time-stamped voltage values of the subset to a predetermined threshold.

12. The method of claim 10, further comprising displaying the determined connections of the plurality of metering nodes to the plurality of transformers in a data structure, the data structure comprising at least one of a list, a spreadsheet, a diagram, a flow-chart, or a map.

13. The method of claim 12, further comprising sending the data structure to a computing device for display.

14. The method of claim 10, further comprising calculating, for a second subset of the plurality of time stamped voltages values that share a second common time-stamp, a second correlation, and comparing the first correlation to the second correlation.

15. The method of claim 14, further comprising displaying the determined connections of the plurality of metering nodes to the plurality of transformers in a data structure, and updating the data structure based on the comparison of the first correlation to the second correlation.

16. A system comprising:
a processing unit configured to perform operations comprising:
receiving a first voltage value associated with a first device;
receiving first location information associated with the first device;
receiving a second voltage value associated with a second device;
receiving second location information associated with the second device;
calculating a correlation between the first and second voltages;
determining connection information of the first device to second device based at least in part on the correlation; and
displaying the connection information on a map, the map showing the first device at a first location corresponding to the first location information and the second device at a second location corresponding to the second location information.

17. The system of claim 16, wherein the first device comprises a first metering node and the second device comprises a second metering node.

18. The system of claim 16, wherein the first device comprises a metering node and the second device comprises a transformer.

19. The system of claim 16, wherein the connection information comprises a power distribution line configuration or location.

20. The system of claim 16, wherein the calculating, determining, or displaying is triggered by a request to generate a report.

21. The system of claim 20, wherein the request to generate a report is initiated responsive to at least one of a power outage, a service call, a discrepancy from a previous correlation, a manual request, or an elapsing of a predetermined amount of time.

22. The system of claim 16, further comprising providing an instruction to service the first device or the second device, based at least in part on the correlation.
